(19) United States
(12) Patent Application Publication
(10) Pub. No.: US 2020/0256914 A1
(43) Pub. Date: Aug. 13, 2020

(54) Slew Rate Programming in Automatic Test Equipment (ATE)

(71) Applicant: NUVOTON TECHNOLOGY CORPORATION, Hsin-chu (TW)

(72) Inventor: Alain Bismuth, Kibbutz Beth Rimon (IL)

(21) Appl. No.: 16/269,573

(22) Filed: Feb. 7, 2019

(51) Int. Cl. G01R 31/28

(52) U.S. Cl. CPC G01R 31/2834; G01R 31/2886

(57) ABSTRACT

An Apparatus for automatic testing of an electronic device includes pin electronics and a controller. The pin electronics includes pin driving circuitry configured to drive input pins of the electronic device with signal levels, and pin measurement circuitry configured to load output pins of the electronic device with loads, and to compare signal levels of the output pins of the device to expected levels. The controller is configured to instruct the pin electronics to connect the pin measurement circuitry to an input pin of the electronic device and, using the pin measurement circuitry, drive the input pin with a signal having a programmable slew-rate by applying a programmable load to the input pin.

### FIELD OF THE INVENTION

The present invention relates generally to automated test equipment, and particularly, to the control of the slew rate in automatic test equipment.

### BACKGROUND OF THE INVENTION

Automatic test equipment (ATE) performs tests on a device, (will be referred to hereinbelow as Device Under Test, or DUT). When the DUT is an electronic component, such as an integrated circuit (IC), the ATE typically applies voltage and current patterns to the DUT inputs, and measures voltages and currents at the DUT outputs.

A summary of ATE technology, including hardware and software, can be found in “Automatic Test Equipment,” Wiley Encyclopedia of Electrical and Electronics Engineering, 1999, by F. Liguori, pages 110-120.

### SUMMARY OF THE INVENTION

An embodiment that is described herein provides an apparatus for automatic testing of an electronic device. The apparatus includes pin electronics and a controller. The pin electronics includes pin driving circuitry configured to drive input pins of the electronic device with signal levels, and pin measurement circuitry configured to load output pins of the electronic device with loads, and to compare signal levels of the output pins of the device to expected levels. The controller is configured to instruct the pin electronics to connect the pin measurement circuitry to an input pin of the electronic device and, using the pin measurement circuitry, drive the input pin with a signal having a programmable slew-rate by applying a programmable load to the input pin.

In an embodiment, the controller is configured to instruct the pin electronics to drive the input pin by applying the programmable load to the input pin through a four-diode bridge, which is configured to terminate a slew of the signal when the signal reaches a programmable level. In some embodiments, the controller is configured to calibrate the input pin by setting a start time of the programmable slew-rate. In an example embodiment, the controller is configured to instruct the pin electronics to measure the signal, and to set the start time of the programmable slew-rate responsively to the measurement results.

There is additionally provided, in accordance with an embodiment that is described herein, a method for automatic testing of an electronic device. The method includes connecting the electronic device to pin electronics, which comprises (i) pin driving circuitry configured to drive input pins of the electronic device with signal levels, and (ii) pin measurement circuitry configured to load output pins of the electronic device with loads, and to compare signal levels of the output pins of the device to expected levels. The pin electronics are instructed to connect the pin measurement circuitry to an input pin of the electronic device, and, using the pin measurement circuitry, to drive the input pin with a signal having a programmable slew-rate by applying a programmable load to the input pin.

There is further provided, in accordance with an embodiment that is described herein, a computer software product for automatic testing of an electronic device. The product includes a tangible non-transitory computer-readable medium in which program instructions are stored, which instructions, when read by a processor that is coupled to pin electronics comprising (i) pin driving circuitry configured to drive input pins of the electronic device with signal levels, and (ii) pin measurement circuitry configured to load output pins of the electronic device with loads, and to compare signal levels of the output pins of the device to expected levels, cause the processor to instruct the pin electronics to connect the pin measurement circuitry to an input pin of the electronic device, and, using the pin measurement circuitry, to drive the input pin with a signal having a programmable slew-rate by applying a programmable load to the input pin.

The present invention will be more fully understood from the following detailed description of the embodiments thereof, taken together with the drawings in which:

### BRIEF DESCRIPTION OF THE DRAWINGS

FIG. 1 is a block diagram that schematically illustrates an Automatic Test Equipment (ATE), in accordance with embodiments of the present invention;

FIG. 2 is a pin-electronics setup screen-shot of ATE, in accordance with an embodiment of the present invention;

FIG. 3 is a DC setup screen-shot of an ATE, in accordance with an embodiment of the present invention;

FIG. 4 is a screen-shot of an ATE test pattern without slew-control, in accordance with an embodiment of the present invention;

FIG. 5 is a diagram of a pattern that generates a non-slew-rate-controlled clock signal, and the resultant waveform, according to an embodiment of the present invention;

FIG. 6 is a diagram of a pattern that generates a slew-rate-controlled clock signal, and the resultant waveform, according to an embodiment of the present invention;

FIG. 7 is a first oscilloscope screenshot of a controlled slew-rate edge, generated by an ATE, in accordance with an embodiment of the present invention;

FIG. 8 is a second oscilloscope screenshot of a controlled slew-rate edge, generated by an ATE, in accordance with an embodiment of the present invention; and

FIG. 9 is a third oscilloscope screenshot of a controlled slew-rate edge, generated by an ATE, in accordance with an embodiment of the present invention.

### DETAILED DESCRIPTION OF EMBODIMENTS

### Overview

Automatic Test Equipment (ATE) for electronic systems and integrated circuits typically comprises “pin electronics” (PE) modules, which are coupled to pins of the Device-Under-Test (DUT). It should be noted that the term PE may alternatively refer to the aggregation of electronic circuits that are coupled to the DUT pins. In the description hereinbelow we will use the term PE to describe an electronic circuit that is coupled to a single DUT pin. The techniques described hereinbelow also apply, mutatis mutandis, to the alternative definition of PE.

Each PE can be controlled to either drive a DUT pin or to measure the voltage level (and/or the current) of a DUT pin. Conventionally, when a PE is coupled to a DUT input pin, the PE will drive the DUT pin; when the PE is coupled to a DUT output pin, the PE will measure the DUT pin; and when the PE is coupled to a DUT Input-Output (I/O) pin, the PE will, at different time periods, drive or measure the DUT pin, as controlled by the ATE software.

The driving circuitry of the PE typically drives an input DUT pin with one of two programmable signal levels (to be described hereinbelow). However, in some applications, input pins should be driven with a programmable slope. For example, a test specification may define that the voltage levels of some of the output pins should be tested when the falling-edge slope of the input clock pin is limited to a rate of 50 mV/ns.

According to embodiments of the present invention, controlled-slope edges may be applied to DUT input pins by configuring the PE to measure the output level of the input pin, and ignore the results of the measurement.

According to embodiments of the present invention, an ATE system comprises software to generate test-patterns. A test routine comprises static PE configuration scripts and dynamic test patterns. The configuration scripts configure drivers and comparators of the PE. For example, the logic-high and logic-low voltage levels with which a PE should drive a DUT input pin (VIH and VIL, respectively), the logic low and logic high voltage levels with which a PE should test a DUT output pin (VOH and VOL), and the load-high and load-low currents with which the PE should load a DUT output pin (IOH, IOL), are statically configured, and remain unchanged during dynamic test pattern execution.

In embodiments of the present invention, the dynamic test patterns dynamically define, for all DUT pins, the driving of DUT input pins and the measurement (including the expected results) of the DUT output pins, at different time periods. Traditionally, the time axis is divided to discrete time-slots, and the dynamic test pattern defines the drive and measurement (e.g. expected results) characteristics in time-slot resolution.

According to embodiments, to drive the DUT pins, PE modules typically comprise a driver with two signal levels: input-low voltage (VIL), and input-high voltage (VIH). Static configuration scripts typically set VIL and VIH values for each of the PE modules, and the dynamic test pattern defines, for each time slot wherein the PE drives the DUT pin, whether the PE should drive the pin with VIH or VIL. For example, a PE may be statically configured to VIL=0.8V and VIH=2.0V, and the dynamic test pattern for the PE may specify 1-1-0-0-1. The PE will drive the DUT pin with signal levels of 2.0V in the first and second time slots, 0.8V in the third and fourth time slots, and 2.0V in the fifth time-slot.

The measurement circuitry of the PE, in accordance with embodiments of the present invention, typically comprises two parts—comparators and load control. The comparators are configured to compare the voltage level on the DUT pin to two voltage levels that are set by a configuration script—Output-Low voltage (VOL), and Output-High voltage (VOH). In time slots where the measurement part (e.g. expected results) of the dynamic test pattern specifies that a logic-high on the pin should be tested, the PE verifies that the voltage on the pin exceeds VOH. In time slots where the test pattern specifies that a logic-low on the pin should be tested, the PE verifies that the voltage on the pin is below VOL.

In an embodiment, the Load control is configured to apply one of two programmable load currents: Output-Low current (IOL) and Output-High current (IOH) to the DUT pin. The two current values are typically programmed in a configuration script (in the description hereinbelow we will refer to current flow from the PE to the pin as positive current, and current from the pin to the PE is negative. Alternatively, we will refer to driving current as “sourcing current”, and, to receiving current as, and “sinking current”). In time slots where the test pattern indicates that the pin is to be tested for logic low, the PE will apply a current equal to IOL to the DUT pin, and when the test pattern indicates that the pin is to be tested for logic high, the PE will apply a current equal to IOH (typically negative) to the DUT pin.

For example, a test script may define, for a DUT pin, that logic-low level (VOL) should be no more than 0.4V with a load current (IOL) of 1.6 mA, and logic-high level (VOH) should be no less than 2.0V with a load current (IOH) of −0.1 mA. The dynamic test pattern, for that output pin, is, in the current example, 1-1-1-0-1-1. The PE will drive the pin with −0.1 mA and check that the pin voltage is more than 2.0V in time-slots 1, 2, 3, 5, 6. In time-slot 4 the PE will drive the pin with 1.6 mA and check that the pin voltage is below 0.4V.

According to embodiments of the present invention, when the test pattern changes from drive logic low to logic high, or vice versa, the signal level at the DUT pin changes at a rate which is a function of the drive circuit characteristics and the load (including the DUT pin and the wiring from the PE to the DUT pin). According to embodiments of the present invention, it may be desirable, in some testing applications, to control the rate at which the signal on a DUT input pin changes. Such control of the signal change-rate is referred to hereinbelow as “slew-rate control” and is typically measured in volt/micro-second.

Some commercial ATE systems comprise circuitry for SR control, or, alternatively, facilitate the addition of an external hardware that generates controlled-SR edges. For example, U.S. Pat. No. 5,642,067, which is incorporated herewith by reference, describes an integrated circuit pulse generator for per pin testing of electronic circuits, which can be added in ATE systems. The pulse generator may control the slew rate of Rising Edge (RE) and Falling Edge (FE) transitions.

Embodiments of the present invention provide for methods and apparatuses for controlling the slew rate in an ATE using the measurement circuitry of the PE, and without the need for additional SR control circuits. In an embodiment, to drive a DUT input pin with a controlled slew rate, the ATE configures the PE that is connected to the corresponding pin as a comparator. For positive edges, the ATE controls the slew rate by programming IOL, and for negative edges the ATE controls the slew rate by programming IOH.

For a capacitive load, slew rate equals, by definition, the current into the DUT pin divided by the equivalent capacitance; and, thus, the slew rate can be controlled by the setting of the IOL and IOH currents.

VREF is set to the voltage level required at the end of the slope; e.g. for a slew-rate-controlled positive edge that starts at 0.1V and ends at 2.4V, VREF is set to 2.4V; for a slew-rate-controlled negative edge that starts at 2.4V and ends at 0.1V, VREF is set to 0.1V.

Thus, according to embodiments of the present invention, slew-rate controlled slopes at DUT pins can be generated using ATE comparator circuits, with no additional circuitry.

### System Description

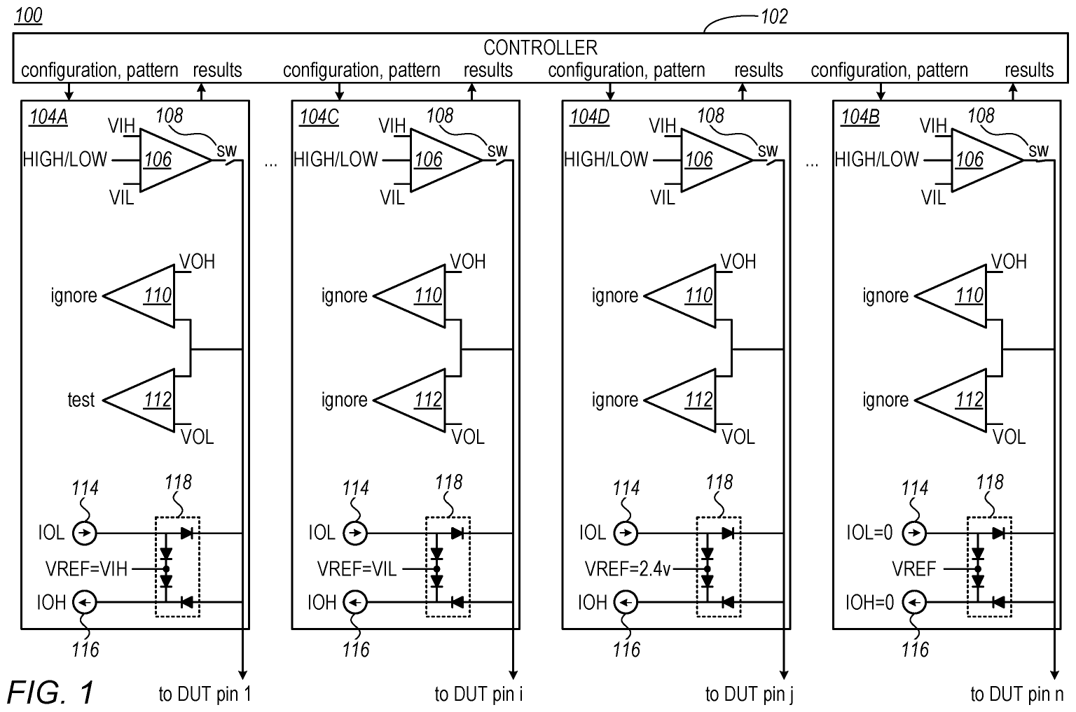

FIG. 1 is a block diagram that schematically illustrates an Automatic Test Equipment (ATE) 100, in accordance with embodiments of the present invention.

ATE 100 comprises a Controller 102, configured to run software programs and to control the ATE operation, and a plurality of Pin Electronic modules (PE) 104, wherein each PE module 104 is coupled to a pin of the Device Under Test (DUT; not shown). The controller is coupled to the PE units using buses, wherein the controller communicates the configurations and dynamic test-patterns to the PEs, and the PEs communicate the test results back to the controller.

To drive the corresponding DUT pin, each PE 104 comprises a Programmable Driver 106, which is configured to output one of two pre-configured signal levels VIL, VIH, according to a control input (designated HIGH/LOW in the figure); and, a Switch 108, which is configured to connect or disconnect the programmable driver from the DUT pin.

To measure the corresponding DUT pin, each PE 104 comprises:

a VOH-Comparator 110, which is configured to verify that the voltage level at the DUT pin is above a pre-configured VOH;

a VOL-Comparator 112, which is configured to verify that the voltage level at the DUT pin is below a pre-configured VOL;

an IOL Programmable Current Source 114, which is configured to source a pre-configured current IOL;

an IOH Programmable Current Source 116, which is configured to sink a pre-configured current IOH; and

A Diode-Bridge 118, comprising four diodes and a programmable voltage source VREF. The Diode Bridge is configured to: a) when the voltage level on the DUT pin is lower than VREF—route the current sourced by IOL Current Source 114 to the DUT pin, and route current sinked by IOH Current Source 116 from the VREF; b) when the voltage level on the pin is higher than VREF—route the current sinked by IOH Programmable Current Source 116 from the DUT pin, and route the current sourced by IOL Current Source 114 to VREF.

The number of PE units that are configured equals to the number of tested DUT pins (when the number of tested pins is lower than the number of PE modules, some of the PE modules may be turned off). FIG. 1 illustrates four PE modules—104A, 104B, 104C and 104D, which are connected to four DUT pins (1, n, i and j, respectively).

PE 104A is configured to test that DUT output pin 1 is at logic-low. (Note that the configuration may change frequently throughout the test. A pin may be tested for logic low in some time-slots and for logic high in other slots, according to the dynamic test pattern. Moreover, IO pins, which are inputs at some time-slots and output at others, can be alternately driven and tested, according to the dynamic test pattern.) Logic Low testing is defined as verifying that the voltage level of the pin, when sourcing IOL, is less than VOL. The controller programs PE 104A so that:
switch 108 is off, disconnecting Programmable Driver 106;
IOL Current Source 114 is set to IOL;
VREF is set to a voltage higher than VOL;
VOL Comparator 112 is set to compare the voltage at the DUT pin to VOL.
VOH comparator is ignored.

Thus, the PE will test that the pin voltage is less than VOL, when sinking IOL (as VOL<VREF, the diode bridge will route the current from IOL Current Source 114 to the DUT pin).

PE 104B is configured to drive DUT input pin n to logic 1 or logic 0, according to the pattern that the controller sets.

The controller programs PE 104B so that switch 108 is on, and Programmable Driver 106 drives the DUT pin with a voltage that equal VIL or VIH, according to the dynamic test pattern.

According to embodiments of the present invention, the same PE 104 can be configured to drive a DUT pin with a programmable slew-rate edge. In the example configuration of FIG. 1, PE 104C drives DUT pin i with a negative slew-rate-controlled edge, whereas PE 104D drives DUT pin j with a positive slew-rate-controlled edge.

To generate a slew-rate-controlled negative edge, the controller programs PE 104C so that:
switch 108 is off, disconnecting Programmable Driver 106;
IOH Current Source 116 is set to a value that corresponds to the slew rate (for example, IOH=C/slew-rate, wherein C is the equivalent capacitance at DUT pin i);
VREF is set to VIL—the voltage at the end of the negative slope.

Thus, PE 104C sinks a pre-configured current from DUT pin i, generating a programmable negative-slope edge. When the voltage at DUT pin i will reach VIL, PE 104C will stop sinking current from the pin.

In a similar manner, to generate a slew-rate-controlled positive edge, the controller programs PE 104D so that:
Switch 108 is off, disconnecting Programmable Driver 106;
IOL Current Source 114 is set to a value that corresponds to the slew rate;
VREF is set to VIH—the voltage at the end of the positive slope.

Thus, PE 104D sources a programmable-value current into DUT pin j, generating a programmable positive-slope edge. When the voltage at DUT pin j will reach VIH, PE 104D will stop sourcing current into the pin.

Thus, according to the example embodiment of FIG. 1, an ATE generates positive and negative programmable-slope edges. The same circuitry that is used to measure output levels with programmable load currents is used to generate the slopes.

As would be appreciated, the structure of ATE 100 and PE 104 described above is cited by way of example. ATEs in accordance to the disclosed techniques are not limited to the description hereinabove.

In some embodiments, some or all the PE units comprise additional circuitry, which is not shown in FIG. 1, for example, for precision analog measurements. In an embodiment, Diode-Bridge 122 comprises similar functionality, implemented with a different circuitry. The switches illustrated in FIG. 1 may be electro-mechanical relays, electronic switches, or a combination of mechanical relays and electronic switches.

In some embodiments, the controller comprises a general-purpose processor and an interface board. In an embodiment, there is no interface board, and the computer communicates directly with PE units 104. In some embodiments, the controller comprises a plurality of processors; in other embodiments, there is no processor in the ATE, and the testing software runs on other computer or computers that are connected to the ATE through a communication network, such as the Internet.

Further embodiments described in the current patent application refer to methods for the generation of programmable slew-rate sloped in an example of a commercial ATE (Chroma 3650-EX), using the VOH-VOL measurement circuitry of the tester. The example ATE is described in Chroma publication 3650-EX-E-201709-500—“SOC/ANALOG TEST SYSTEM MODEL 3650-EX,” 2017, which is incorporated herewith by reference.

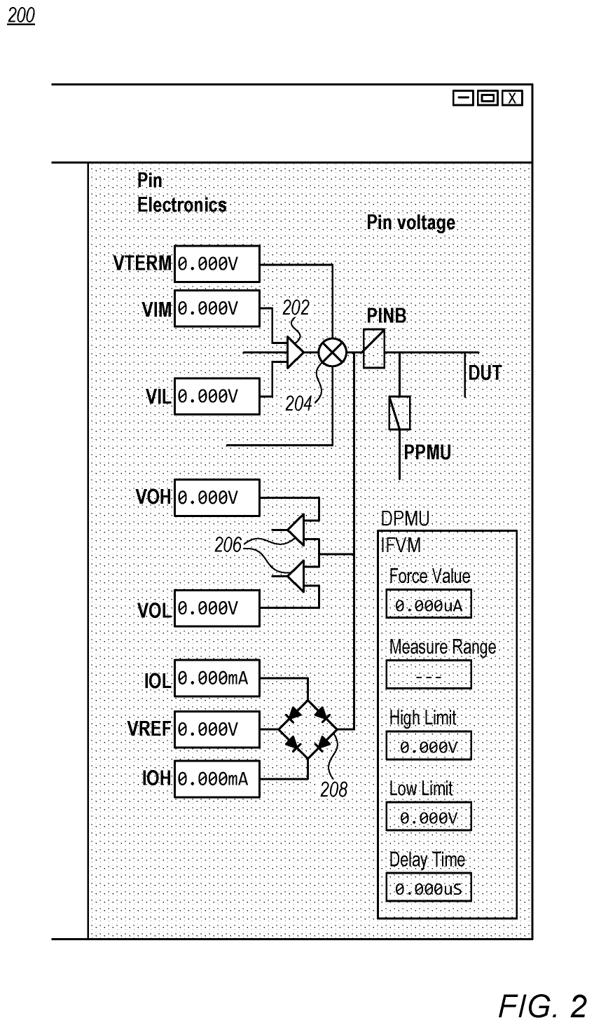

FIG. 2 is a pin-electronics setup screen-shot 200 of a PE, in accordance with an embodiment of the present invention. The screen-shot is part of the Graphic-User-Interface (GUI), which allows the user to easily program the PE setup.

The screenshot comprises a Programmable Driver 202 (106 in FIG. 1), which can drive the DUT pin with a configurable voltage level VIL or VIH (according to the dynamic test pattern); a Switch 204 (108 in FIG. 1), which is configured to connect Driver 202 to the DUT pin, according to the dynamic test pattern; VOH-VOL Comparators 206, which are configured to compare the voltage on the DUT pins with configurable VOH and VIL values; and, a Load Unit 208, comprising a diode bridge, with IOL and IOH current sources (similar to units 114, 116, and 118 of FIG. 1). All configurable parameters VIH, VIL, VOH, VOL, IOH, IOL and VREF can be configured using test scripts, or, by entering the desired values in the numerical-entry sub-windows shown in FIG. 2 (In some commercial testers. Entering the desired value in numerical-entry sub-windows is limited to debug mode only).

According to embodiments of the present invention, a user can program the ATE to generate slew-rate controlled edges by setting switch 204 to Off, entering current values to IOL (for positive edges) or IOH (for negative edges, and, setting VREF to the voltage level at the end of the slope.

As would be appreciated, screen-shot 200 described above is cited by way of example. In alternative embodiments the values of VIH, VIL, VOH, VOL, IOL, IOH and VREF can be programmed using any other GUI, or, for example, using non-graphical programming scripts.

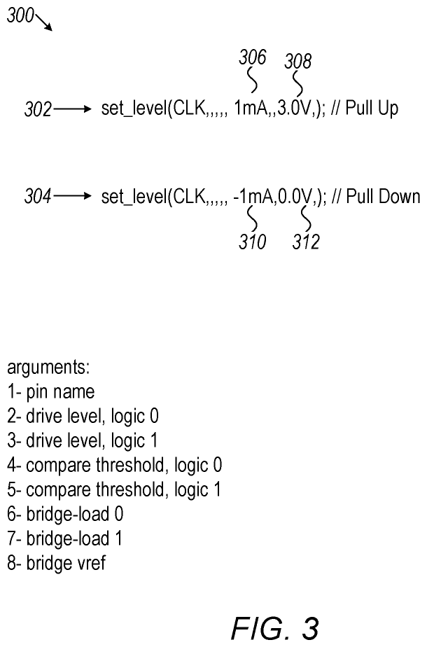

FIG. 3 is a DC setup screen-shot 300 of an ATE, in accordance with an embodiment of the present invention. The screen-shot comprises two set_level commands, for setting a positive (Pull-Up) and a negative (Pull-Down) edge. Set_level commands are typically embedded in static configuration scripts.

In the example embodiment, a set_level command receives eight ordered arguments:
1. pin name
2. drive level, logic low (VIL in FIG. 2)
3. drive level, logic high (VIH in FIG. 2)
4. compare threshold, logic low (VOL in FIG. 2)
5. compare threshold, logic high (VOH in FIG. 2)
6. Bridge, logic-low load (IOL in FIG. 2)
7. Bridge, logic-high load (IOH in FIG. 2)
8. Bridge, VREF

When the value of any argument is not specified (e.g., a space is inserted in the command), the value that had been programmed for that argument remains unchanged.

According to the example embodiment illustrated in FIG. 3, the first set_level command comprises a Bridge-Low-Load argument 302, which is set to 1 mA; and a Bridge-VREF argument 304, which is set to 3.0V. Similarly, the second set_level command comprises a Bridge-High-Load argument 306, which is set to −1 mA; and a Bridge-VREF argument 308, which is set to 0.0V.

Thus, according to the example embodiment of FIG. 3, the first set_level command sets the PE that is connected to pin CLK of the DUT to source 1 mA into the DUT pin, whereas the second set_level command sets the PE to sink 1 mA from the DUT pin. In both cases, current will be applied to the pin only when, according to the pattern, the DUT pin will be in Output mode (e.g. switch 108 of FIG. 1 is off).

As would be appreciated, the Set-Level commands illustrated in FIG. 3 and described above are cited by way of example. In alternative embodiments other suitable formats may be used; in an embodiment the values of IOH, IOL and VREF are manually entered, using a GUI.

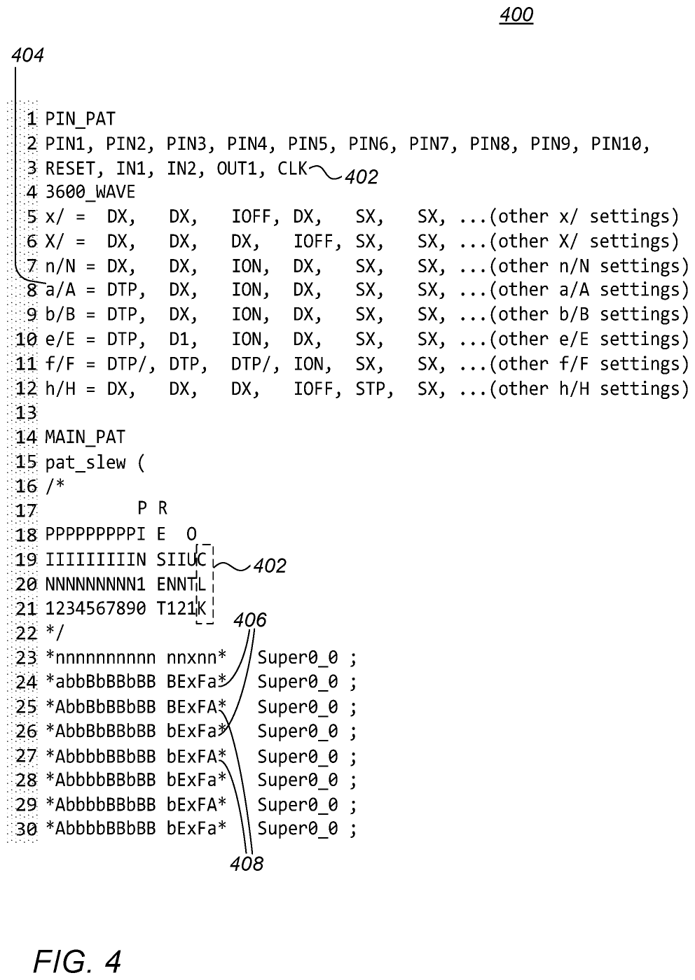

FIG. 4 is a screen-shot of an ATE test pattern without slew-rate control, in accordance with an embodiment of the present invention. According to the example embodiment of FIG. 4, the test pattern comprises a PIN_PAT part, wherein an ordered list of pin names is defined; a WAVE part (3600_WAVE in the figure), wherein symbols to be used in the main-pattern part are defined, and a main-pattern part (MAIN_PAT in the figure), which defines the programming of all pins in all time-slots of the pattern. (The PIN_PAT and WAVE part are configuration scripts, whereas the MAIN_PAT part is the dynamic test-pattern).

According to the example embodiment of FIG. 4, an ATE time-slot is divided to six separately-programmable “periods”. The timing of the periods is defined in a “timing-set”, which is part of the test setup (e.g. a configuration script), and is not shown. It should be noted that the periods are not necessarily mutually exclusive.

Each line of the WAVE part of the test-pattern comprises:
1. A symbol, or a pair of lower-case and upper-case symbols. The symbols will be used in the dynamic test pattern. When a pair of lower-case and upper-case letters is indicated, the lower-case letter indicates logic-low level, and the upper-case letter indicates logic high level.
2. Following the equal sign, six indications to the six states of the PE, during the six periods of the time-slot.
3. Additional symbol information (not relevant to the present invention).

The six periods of a time slot are referred to hereinbelow as T1 through T6. T1 and T2 define drive periods. T3 and T4 define switching from drive to compare (but can be also used to define drive periods, like T1 and T2). T5 and T6 define compare periods.

Definition of the Period Terms Used in the WAVE Part (First Six Parameters Following the Equal Sign):
DX: Drive, value=x (don't care). The PE setting during this period will not change (remains as it was in the previous period).
IOFF: The PE is comparator at that period (driver 106 is turned off).
ION: driver 106 is turned on
SX: S for strobe and X for don't care. The ATE is in compare mode but ignores fail/pass results (yet IOH and IOL are on).
DTP: Drive data. Drive 0 or 1, according to the case of the symbol in the pattern part (e.g., for a/A symbol, drive the pin with logic low when an “a” is indicated in the pattern, and with logic-high when an “A” is indicated).
D1: Drive a logic “1” at that period, regardless of the pattern data.
DTP/: Similar to DTP, but the driven data is inverted (i.e. drive low for an upper case pattern symbol; drive high for a lower case symbol)
h/H labels—same as above
STP: Compare.

The third part of the test pattern is the dynamic pattern (MAIN_PAT). The pattern comprises a commented pin-name header, followed by lines of symbols. The lines correspond to consecutive time slots; each line comprises symbols, wherein consecutive symbols define the pattern at the corresponding time-slot, for consecutive PE modules.

The symbol “Super0_0, at the end of each pattern line, specifies a “timing set”, which is part of the test configuration script and defines the timing values for the six periods.

A symbol a/A is selected for the clock pin in the WAVE part (404) with the following definitions:
DTP in period 1 (drive data)
DX in period 2—continue driving data
ION in period 3 (Driver 106 is turned on)
DX in period 4—no change from period 3
SX in periods 5 and 6 (compare; ignore the results (IOL and IOH are off since ION is programmed in T3).

In the pattern part of the screenshot, after a first initialization time-slot (symbol “n”), the test pattern sets the PE associated with the clock pin, alternately, to symbol “a” (406) in even line numbers, and to symbol “A” (408) in even line numbers.

Thus, according to the example embodiment of FIG. 4, the PE 104 that is coupled to CLK pin applies alternate logic-high and logic-low to the CLK pin. The slope is not controlled, and is determined by the drive capability of driver 106 and the equivalent impedance on the CLK pin.

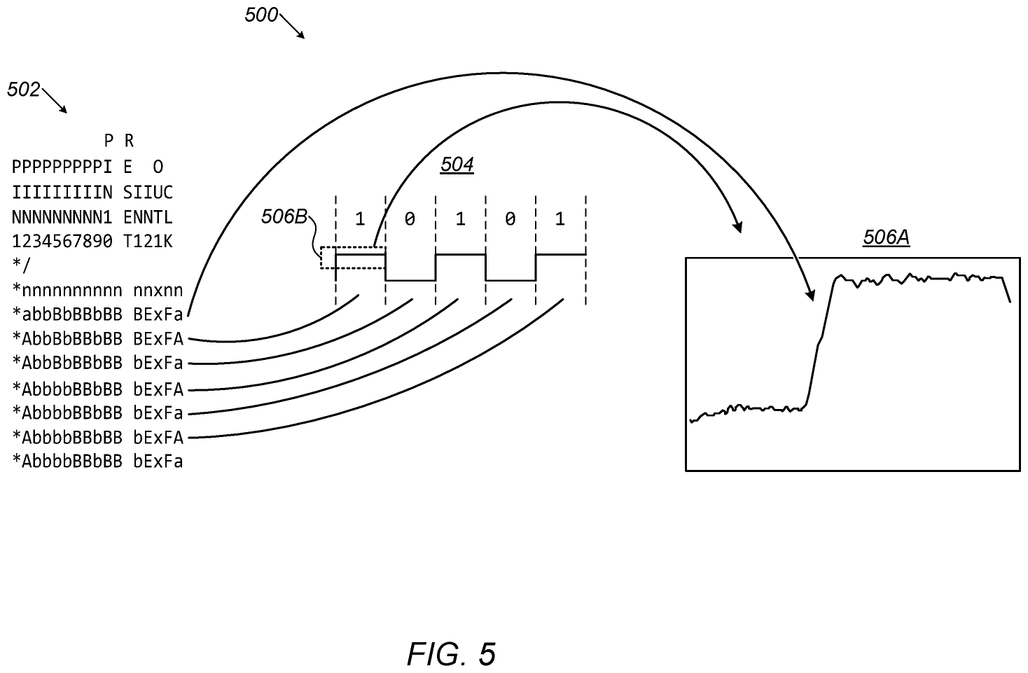

FIG. 5 is a diagram 500 of a pattern that generates a non-slew-rate-controlled clock signal, and the resultant waveform, according to an embodiment of the present invention. The diagram comprises a dynamic test-pattern 502, which is identical to the test-pattern part of FIG. 4, a conceptual waveform 504, and an oscilloscope screen-shot 506A, which illustrates the actual waveform that was captured when a Chroma 3650-EX ATE was programmed with the said test pattern.

Conceptual waveform 504 is at logic-high for test pattern lines wherein CLK is programmed with symbol A, and logic-low in lines wherein CLK is programmed with symbol a.

Oscilloscope screen-shot 506A illustrates a portion 506B of the test pattern. The low-to-high transition is fast, limited by the drive capability of driver 106, and the equivalent impedance of the CLK pin.

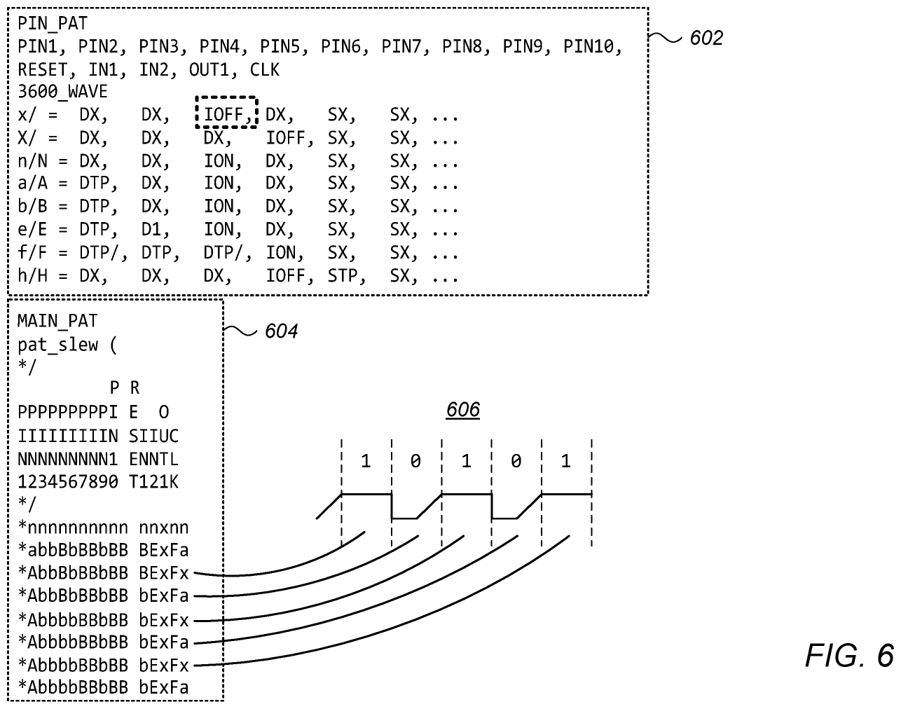

FIG. 6 is a diagram 600 of a pattern that generates a slew-rate control clock signal, and the resultant waveform, according to an embodiment of the present invention. The diagram comprises a PIN-PAT and WAVE definition 602 (which is identical to the PIN-PAT and WAVE parts illustrated in FIG. 4), a Test-Pattern 604, a Theoretical Waveform 606, and an oscilloscope screen-shot 608.

The difference between test-pattern 604 and test-pattern 400 of FIG. 4 is that, in FIG. 4 the symbol for CLK pin in even lines is a, whereas the symbol in test-pattern 604 is x.

According to the example embodiment of FIG. 6, the CLK is applied with controlled slew-rate rising edge. Test-pattern 604 alternately assign x and a symbols to the CLK pin. “a” is defined (in 602) as:

DTP, DX, ION, DX, SX, SX;

whereas x is defined (in 602) as:

DX, DX, IOFF, DX, SX, SX.

In a dynamic test-pattern line wherein the symbol for the CLK pin is “a”, the PE will turn driver 106 on, and drive the signal with a logic low. In the subsequent test pattern line, the symbol for the CLK pin is x, driver 106 will be turned off, and current sources IOL, IOH will be turned on. As VREF is programmed to 3V, IOL current source 116 (FIG. 1) will source current (equal to the setting of IOL) to the CLK pin, through Bridge 118, and a rising edge controlled-slew-rate will be generated.

Thus, according to the example embodiment that was described hereinabove with reference to FIG. 6, an ATE that does not comprise a dedicated controlled-slew rate pulse generator can be configured, by software control, to generate a controlled-slew-rate slope.

As would be appreciated, the programming of the ATE described in FIGS. 300 and 600 above is cited by way of example. Programming of ATEs in order to generate controlled-slew-rate slopes in accordance to the disclosed techniques comprise disconnecting a pin driver and connecting measurement loads to the pin. However, the programming constructs are not limited to the description hereinabove, which is compatible with Chroma testers. Alternative embodiments of the present invention may use programming constructs that are compatible with other testers.

The programming example of FIG. 6 generates a positive slew-rate controlled slope. To generate positive slew-rate controlled slopes, the same pattern (604) may be used, wherein all occurrences of an “a” symbol in the CLK column are replaced by “A”, and wherein the set_level command preceding the pattern will set VREF to the voltage level at the end of the negative slope (for example, set_level command 302 may be used, with VREF=0.0V).

Correction of the ATE Board Calibration

According to some embodiments of the present invention, the ATE may comprise On-Board calibration, which corrects the edge placement of the digital edges around a pre-required voltage, moving the timing of the edge start as required. When a programmable slew-rate edge is generated, the pin falling/rising edges may shift in time, disrupting the edge calibration.

In an embodiment, the placement of the edge (in time) is measured with an oscilloscope, and the timing of the pin is corrected to compensate for any misplacements. In some embodiments, a pin compare format is used to characterize the pin slope and correct the timing setup.

Results

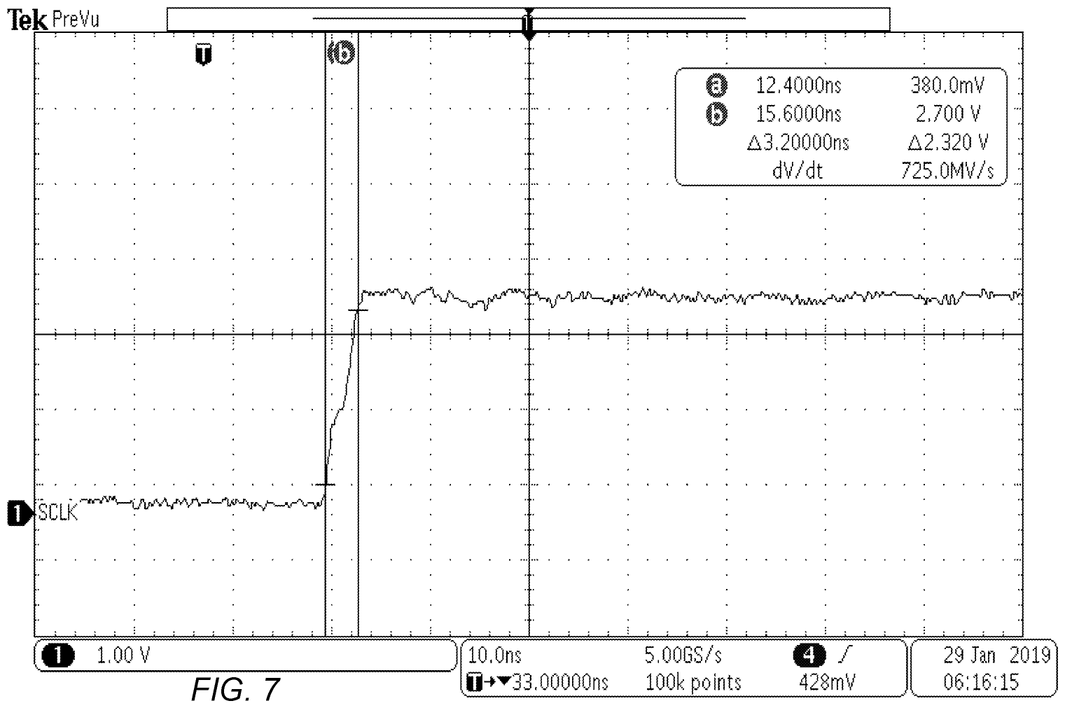

FIG. 7 is an oscilloscope screenshot of a non-controlled slew-rate edge, generated by an ATE, in accordance with an embodiment of the present invention. driver 116 (FIG. 1) is programmed to drive the the DUT pin high. The slew rate is not controlled, set by the internal impedance of driver 106 and the impedance of the DUT pin

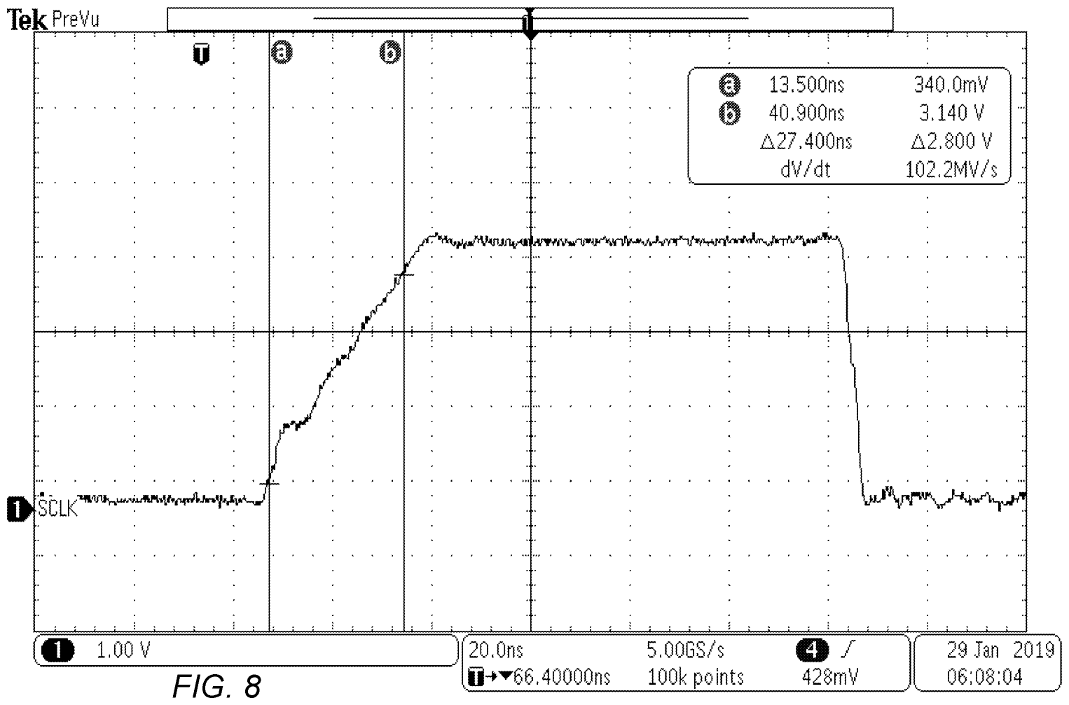

FIG. 8 is a first oscilloscope screenshot of a controlled slew-rate edge, generated by an ATE, in accordance with an embodiment of the present invention. IOL source 114 (FIG. 1) is programmed to source 13 mA into the DIT pin. As can be seen, the average slew rate generated is 102.2 MV/S (102.2 mV/ns).

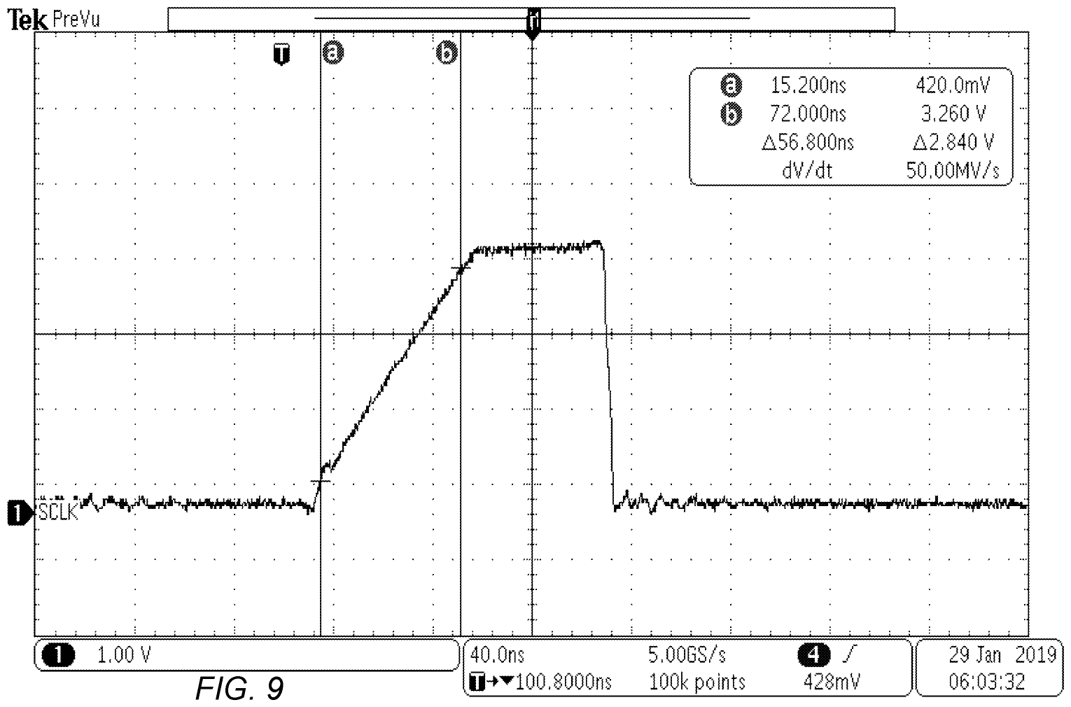

FIG. 9 is a second oscilloscope screenshot of a controlled slew-rate edge, generated by an ATE, in accordance with an embodiment of the present invention. IOL source 114 (FIG. 1) is programmed to source 6 mA from the DIT pin. As can be seen, the average slew rate generated is 50.0 MV/S (50.0 mV/ns).

The settings and the programming of the various units of the ATE and the screenshot of the resultant waveforms, shown in FIGS. 2 through 9, are example settings, programming and results that are shown purely for the sake of conceptual clarity. Any other suitable setting and programming can be used in alternative embodiments, and the results may vary accordingly. In particular, the setting and programming are suitable for a Chroma tester; setting and programming for other testers may vary according to the hardware setup and the programming interface of other testers. PE 104 (FIG. 1) may be a single integrated circuit, an aggregation of a plurality of integrated circuits, a multi-chip-carrier or a PCB. In some embodiments, groups of PEs, or all PEs, may be aggregated in the same physical enclosure (for example—in a single integrated circuit).

Parts of ATE 100, such as Controller 102, may be implemented by hardware, by software, or by combination of hardware and software. Controller 102 and/or PE 104 may be a Field-Programmable-Gate-Array (FPGA), an Application Specific Integrated Circuit (ASIC), or a combination of FPGA and ASIC.

In some embodiments, controller 102 comprises a general-purpose programmable processor, which is programmed in software to carry out the functions described herein. The software may be downloaded to the processor in electronic form, over a network, for example, or it may, alternatively or additionally, be provided and/or stored on non-transitory tangible media, such as magnetic, optical, or electronic memory.

It will thus be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An Apparatus for automatic testing of an electronic device, the apparatus comprising:
pin electronics, which comprises:
pin driving circuitry configured to drive input pins of the electronic device with signal levels; and
pin measurement circuitry configured to load output pins of the electronic device with loads, and to compare signal levels of the output pins of the device to expected levels; and
a controller, configured to instruct the pin electronics to connect the pin measurement circuitry to an input pin of the electronic device and, using the pin measurement circuitry, drive the input pin with a signal having a programmable slew-rate by applying a programmable load to the input pin.

2. The apparatus according to claim 1, wherein the controller is configured to instruct the pin electronics to drive the input pin by applying the programmable load to the input pin through a four-diode bridge, which is configured to terminate a slew of the signal when the signal reaches a programmable level.

3. The apparatus according to claim 1, wherein the controller is configured to calibrate the input pin by setting a start time of the programmable slew-rate.

4. The apparatus according to claim 3, wherein the controller is configured to instruct the pin electronics to measure the signal, and to set the start time of the programmable slew-rate responsively to the measurement results.

5. A method for automatic testing of an electronic device, the method comprising:
connecting the electronic device to pin electronics, which comprises:
pin driving circuitry configured to drive input pins of the electronic device with signal levels; and
pin measurement circuitry configured to load output pins of the electronic device with loads, and to compare signal levels of the output pins of the device to expected levels; and
instructing the pin electronics to connect the pin measurement circuitry to an input pin of the electronic device, and, using the pin measurement circuitry, to drive the input pin with a signal having a programmable slew-rate by applying a programmable load to the input pin.

6. The method according to claim 5, wherein instructing the pin electronics to drive the input pin comprises applying the programmable load to the input pin through a four-diode bridge, which is configured to terminate a slew of the signal when the signal reaches a programmable level.

7. The method according to claim 5, and comprising calibrating the input pin by setting a start time of the programmable slew-rate.

8. The method according to claim 7, and comprising instructing the pin electronics to measure the signal, and to set the start time of the programmable slew-rate responsively to the measurement results.

9. A computer software product for automatic testing of an electronic device, the product comprising a tangible non-transitory computer-readable medium in which program instructions are stored, which instructions, when read by a processor that is coupled to pin electronics comprising (i) pin driving circuitry configured to drive input pins of the electronic device with signal levels, and (ii) pin measurement circuitry configured to load output pins of the electronic device with loads, and to compare signal levels of the output pins of the device to expected levels, cause the processor to instruct the pin electronics to connect the pin measurement circuitry to an input pin of the electronic device, and, using the pin measurement circuitry, to drive the input pin with a signal having a programmable slew-rate by applying a programmable load to the input pin.

10. The product according to claim 9, wherein the instructions cause the processor to instruct the pin electronics to drive the input pin by applying the programmable load to the input pin through a four-diode bridge, which is configured to terminate a slew of the signal when the signal reaches a programmable level.

11. The product according to claim 9, wherein the instructions cause the processor to calibrate the input pin by setting a start time of the programmable slew-rate.

12. The product according to claim 11, wherein the instructions cause the processor to instruct the pin electronics to measure the signal, and to set the start time of the programmable slew-rate responsively to the measurement results.
